(19) United States
(12) Patent Application Publication
(10) Pub. No.: US 2009/0267808 A1
(43) Pub. Date: Oct. 29, 2009

(54) Key for an Input Device

(75) Inventors: Yen-Hung Lin, Taoyuan City (TW); Chang-Hua Wei, Taoyuan City (TW); Shih-Hsun Ou, Taoyuan City (TW)

Correspondence Address: GROSSMAN, TUCKER, PERREAULT & PFLEGER, PLLC, 55 SOUTH COMMERICAL STREET, MANCHESTER, NH, 03101, US

(73) Assignee: HTC CORPORATION, Taoyuan City (TW)

(21) Appl. No.: 12/412,580

(22) Filed: Mar. 27, 2009

(30) Foreign Application Priority Data
Apr. 25, 2008 (TW) 097115411

(51) Int. Cl. H03M 11/00

(52) U.S. Cl. 341/22

(57) ABSTRACT

An input device comprises a plurality of keys, and each of the keys has a pattern. The pattern is a portion of a complete character. The complete character comprises a character feature according to which the character can be recognized, and the aforementioned pattern comprises the character feature.

This application claims priority to Taiwan Patent Application No. 097115411 filed on Apr. 25, 2008, the disclosure of which is incorporated herein by reference in its entirety.

### CROSS-REFERENCES TO RELATED APPLICATIONS

Not applicable.

### BACKGROUND OF THE INVENTION

1. Field of the Invention

The present invention provides a key for an input device, which comprises a plurality of such keys. In particular, a key comprises a pattern and a corresponding input device thereof, wherein the pattern is a portion of a complete character.

2. Descriptions of the Related Art

Because modern science and technologies have developed rapidly, a wide variety of lightweight and miniaturized electronic apparatuses have been put into the market, which is especially the case for handheld electronic apparatuses such as mobile phones, personal digital assistants (PDA) and the like. To improve the portability of such products, almost all manufactures are directing great efforts to develop miniaturized products with a slimmer profile.

Manufacturers who formulate the specifications for such handheld electronic products usually consider whether the characters on the keys are recognizable to the users. Therefore, when the products are designed, there is a limitation to how small the characters may be for the user to recognize. If the size of the characters were too small, most of the user would not be able to recognize, and it would be possible of the situation that the user would fail to identify the desired keys or press the unwanted keys if the keys were made with such size of characters. Therefore, with the restriction of the characters for identification, the size of the handheld electronic product is limited.

In view of this, efforts still have to be made in the art to provide an input device, in which the characters on the keys are legible enough for the eyes to recognize so that the handheld electronic products using such an input device will have a smaller size.

### SUMMARY OF THE INVENTION

Based on the problems of the prior art, the primary objective of this invention is to provide the key of an input device, which comprises a pattern. The pattern is a portion of a complete character, and comprises a character feature which is adapted to have a user to recognize the complete character.

Another objective of this invention is to provide an input device with a plurality of such keys.

Because handheld electronic apparatuses are becoming more lightweight and miniaturized, in order to have a smaller size of the product and consider the limitation of the characters for users to recognize, the invention of the input device designed with the recognition ability of people and the common knowledge of existing numerals, alphabet (i.e. the alphabet has 26 letters), phonetic notations, punctuation marks or characters, presents patterns that have partial characteristics of a character feature on a key that are recognizable by users. In terms of the character feature, for example, the numerals 2 and 3 are distinct from each other in the radian of respective upper portions, as is also the case for the numerals 8 and 9. Hence, different numerals have respective character features are distinguishable. Of course, patterns presented by the character features are also distinct. With this invention, the input device can be smaller while still maintaining recognizable key characters.

In summary, the most important technical measures and inventive features of this invention lie in the manner and configuration in which the pattern is presented; that is, the character features are adapted to be recognized by the user.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a schematic view of an input device of the first embodiment of this invention;

FIG. 2 is a schematic view of a key 11h in the input device of FIG. 1;

FIG. 3 is a schematic view illustrating the upper portion where a pattern is located and occupies 55% of a first complete character;

FIG. 4 is a schematic view of an input device of the second embodiment of this invention;

FIG. 5 is a schematic view of a key 11t in the input device of FIG. 4;

FIG. 6 is a schematic view of an input device of the third embodiment of this invention;

FIG. 7 is a schematic view of a key 15h in the input device of FIG. 6;

FIG. 8 is a schematic view illustrating that the lower portion where a pattern is located and occupies 60% of the first complete character;

FIG. 9 is a schematic view of an input device of the fourth embodiment of this invention;

FIG. 10 is a schematic view of a key 15t in the input device of FIG. 9;

FIG. 11 is a schematic view of an input device of the fifth embodiment of this invention;

FIG. 12 is a schematic view of a key 17h in the input device of FIG. 11;

FIG. 13 is a schematic view illustrating that the left portion where a pattern is located and occupies 45% of the first complete character;

FIG. 14 is a schematic view of an input device of the sixth embodiment of this invention;

FIG. 15 is a schematic view of a key 17t in the input device of FIG. 14;

FIG. 16 is a schematic view of an input device of the seventh embodiment of this invention;

FIG. 17 is a schematic view of a key 19h in the input device of FIG. 16;

FIG. 18 is a schematic view illustrating that the right portion where a pattern is located and occupies 70% of the first complete character;

FIG. 19 is a schematic view of an input device of the eighth embodiment of this invention; and

FIG. 20 is a schematic view of a key 19t in the input device of FIG. 19.

### DESCRIPTION OF THE PREFERRED EMBODIMENT

In the following description, the key of an input device in accordance with this invention will be explained with reference to the embodiments thereof. However, these embodiments are not intended to limit this invention to any specific context, applications or particular implementations. Therefore, description of these embodiments is only intended to illustrate but not to limit this invention. It should be noted that in the following embodiments and the attached drawings, elements indirectly related to this invention are omitted from depiction; and for ease of understanding, elements are depicted in a schematic way and thus, are unnecessarily in absolute scale relationships with actual elements in terms of dimensions and profiles.

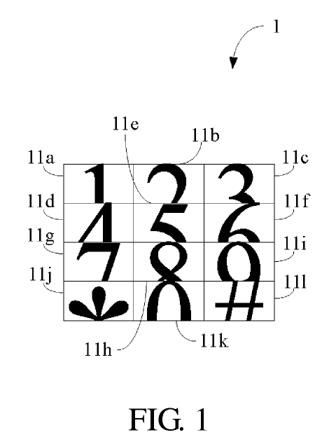

FIG. 1 depicts the first embodiment of this invention, which is an input device 1. In this embodiment, the input device 1 is a touch panel of a handheld electronic apparatus, e.g., a mobile phone. In other embodiments, however, the input device 1 may also be a physical keyboard. Furthermore, the input device 1 may also be used for other handheld electronic apparatuses, a keyboard, a phone, a notebook or other electronic products provided with keys. The input device 1 of this embodiment comprises a plurality of keys 11a˜11l, each of which has a pattern respectively.

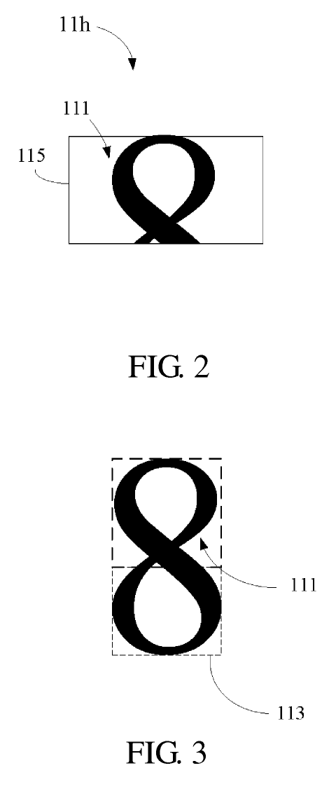

Because this embodiment is used for a mobile phone which is a kind of handheld electronic apparatus, “numeral” characters most commonly used in mobile phones will be described herein. In other embodiments, however, the character may also be a letter, a phonetic notation, a punctuation mark, a character or an icon. For example, FIG. 2 depicts a schematic view of a key 11h presenting the numeral 8, and FIG. 3 depicts a schematic view of a first complete character 113. In case of a physical key, the key 11h may comprise a pattern 111 and a key body 115, and the first complete character 113 comprises the pattern 111. Alternatively, in case of a virtual key presented on a touch panel, the key 11h comprises only a pattern 111. The manners in which the pattern 111 are determined and features thereof will be described in detail hereinafter.

As shown in FIGS. 2 and 3, the pattern 111 is formed on the key body 115. Alternatively, the pattern 111 may also be presented virtually without a key body 115. The pattern 111 is a portion of the first complete character 113. The first complete character 113 comprises a character feature adapted to be recognized, and the pattern 111 includes this character feature. The character feature indicates a portion of a character that is adapted to distinguish the character from others, which varies according to the associated fonts, the selected area or the like. For purpose of description, the following embodiments will be described with reference to the exemplary font “Times New Roman”, although they are not solely limited thereto. Furthermore, the following description will be made with reference to patterns presented by simply capturing the top, bottom, left or right square block from a complete character respectively, although top left, bottom left, top right, bottom right or other portions may also be captured from a complete character. These patterns adapted to be recognized by the user may correspondingly be scaled up, scaled down or remain on the original scale according to area of the key itself, the appearance design of an associated handheld apparatus or other considerations. The term “scale” referred to herein means the scale of the pattern relative to the first complete character.

In this embodiment, the pattern 111 is an upper portion of the first complete character 113, which occupies 55% of the first complete character 113. That is, the upper portion presented with the pattern 111 is an upper area captured from the first complete character 113 that occupies 55% of first complete character 113. This 55% adopted herein is adapted to allow the upper portions of numerals on all keys 11a˜11l to represent character features of the corresponding numerals, and the so-called character features in turn allow the user to recognize the individual numerals. However, it should be noted that the percentage of the upper portion which occupies the first complete character 113, is not merely limited to 55%, and may also range from 55% to 100% in other embodiments.

In reference to the input device 1 of FIG. 1, a user can readily recognize the numerals represented by the individual keys with the patterns 111 presented on the keys. The user is then able to press one of the keys 11a˜11l as needed. In practice, each of the keys is adapted to generate a corresponding key-pressing signal, which is routed through a circuit board and transmitted to a control circuit. Upon receiving the corresponding key-pressing signal, the control circuit proceeds to process the key-pressing signal so that the input device can give a corresponding visual display or take other actions, for example, to make a call. As shown in FIG. 2, once the user presses the key 11h corresponding to the numeral 8, the key 11h generates a key-pressing signal corresponding to the numeral 8 for transmission to the control circuit, so that the input device 1 may display the numeral 8 or take other intended actions.

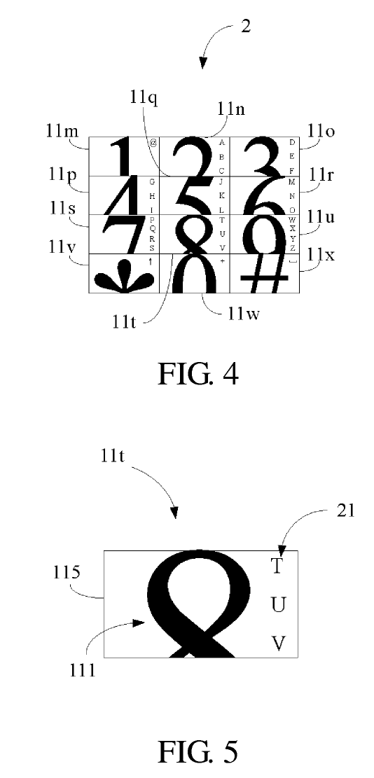

FIG. 4 depicts the second embodiment of this invention, which is an input device 2. The input device 2 comprises a plurality of keys 11m˜11x. The input device 2 of the second embodiment has substantially the same circuit connections as the input device 1 of the first embodiment, while the captured portion is also an upper area that occupies 55% of the first complete character. Thus, these will not be further described herein. The input device 2 of this embodiment is used for a physical keyboard or a virtual key of a handheld electronic apparatus, e.g., a mobile phone. Typically in a physical keyboard or virtual keys of a mobile phone, each key is able to input different characters by switching the input methods. Accordingly, as depicted in FIG. 5, this embodiment differs from the first embodiment in that each of the keys in the input device 2 further comprises a plurality of second complete characters 21 to meet the need for different characters in different input methods. The second complete characters 21 includes A˜Z, ↑, +, [symbol] , which are dispersedly arranged on individual keys respectively with each key having a particular number of such characters thereon. The contents A˜Z, ↑, +, [symbol] of the second complete characters 21 set forth herein are only for purpose of illustration, and may also be a phonetic notation, a punctuation mark, a character or an icon in other embodiments. As depicted in FIG. 5, the second complete characters 21 of this embodiment are arranged to the right of the pattern 111. In other embodiment, however, the second complete characters 21 are not just limited to such a location, but may also be formed at any locations on the key body 115. Furthermore, the electronic apparatus that adopts the input device 2 are not merely limited to what is described above as well as the amount and the arrangement of the second complete characters 21.

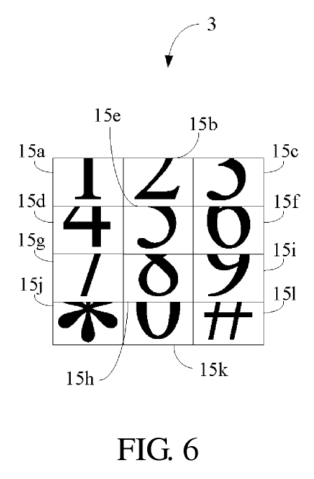

FIG. 6 depicts the third embodiment of this invention, which is an input device 3. In this embodiment, the input device 3 is a touch panel of a handheld electronic apparatus, e.g., a mobile phone. In other embodiments, however, the input device may also be a physical keyboard. Furthermore, the input device 3 may also be used in other handheld electronic apparatuses, a keyboard, a phone, a notebook or other electronic products provided with keys. In practice, the input device 3 of this embodiment may comprise a plurality of keys 15a˜15l and a control circuit. The input device 3 of this embodiment has substantially the same circuit connections as the first embodiment, and thus, this will not be further described herein.

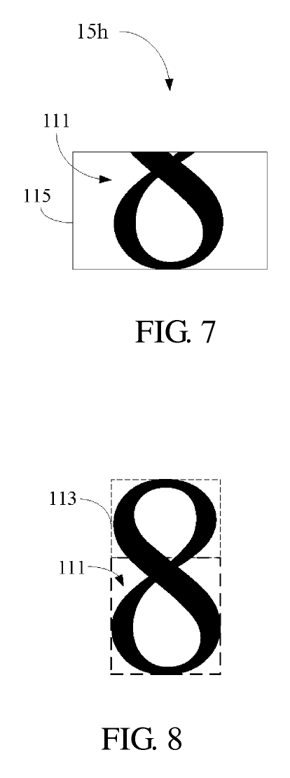

Referring to FIGS. 7 and 8, this embodiment differs from the first embodiment in that the pattern 111 is a lower portion of the first complete character 113, which occupies 60% in area of the first complete character 113. In other words, the pattern 111 occupies 60% of the first complete character 113, i.e., the lower portion presented with the pattern 111 is a lower area captured from the first complete character 113 that occupies 60% of the first complete character 113. The 60% adopted herein is adapted to allow the lower portions of numerals on all keys 15a˜15l to represent character features of the corresponding numerals, and the so-called character features in turn allow the user to recognize the individual numerals. However, it should be noted that the percentage of the lower portion which occupies the first complete character 113, is not merely limited to 60%, and may range from 60% to 100% in other embodiments. In practice, a user may readily recognize numerals represented by individual keys with the character features presented on the keys, and then press one of the keys 15a˜15l as needed to generate a corresponding key-pressing signal, which is routed through a circuit board and transmitted to the control circuit. Upon receiving the corresponding key-pressing signal, the control circuit proceeds to process the signal so that the input device 3 can give a corresponding visual display or take other actions.

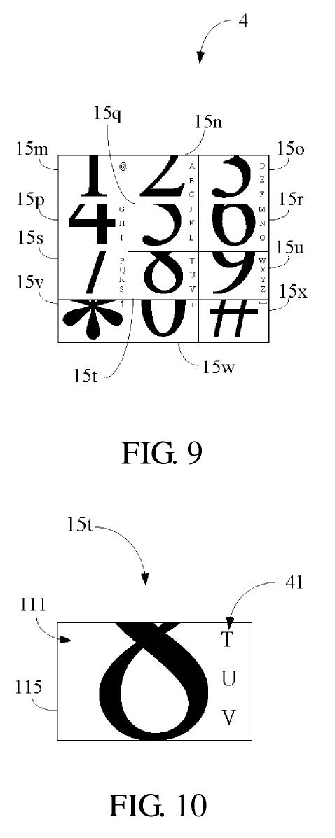

FIG. 9 depicts the fourth embodiment of this invention, which is an input device 4. The input device 4 comprises a plurality of keys 15m˜15x. The input device 4 of the fourth embodiment has substantially the same circuit connections as the input device 3 of the third embodiment. The captured portion is also a lower area that occupies 60% of the first complete character. Thus, these will not be further described herein. The input device 4 of this embodiment is used for a physical keyboard or a virtual key of a handheld electronic apparatus. Typically, in a physical keyboard or virtual keys of a mobile phone, each key is able to input different characters by switching the input methods. Accordingly, as depicted in FIG. 10, this embodiment differs from the third embodiment in that each of the keys in the input device 4 further comprises a plurality of second complete characters 41 to meet the need for different characters in different input methods. The second complete characters 41 includes A˜Z, ↑, +, [symbol] , which are dispersedly arranged on individual keys respectively with each key having a particular number of such characters thereon. The contents A˜Z, ↑, +, [symbol] of the second complete characters 41 set forth herein are only for purpose of illustration, and may also be a phonetic notation, a punctuation mark, a character or an icon in other embodiments. As depicted in FIG. 10, the second complete characters 41 of this embodiment are arranged to the right of the pattern 111. In other embodiment, however, the second complete characters 41 are not just limited to such a location, but may also be formed at any locations on the key body 115. Furthermore, the electronic apparatus that adopts the input device 4 are not merely limited to what is described above as well as the amount and the arrangement of the second complete characters 41.

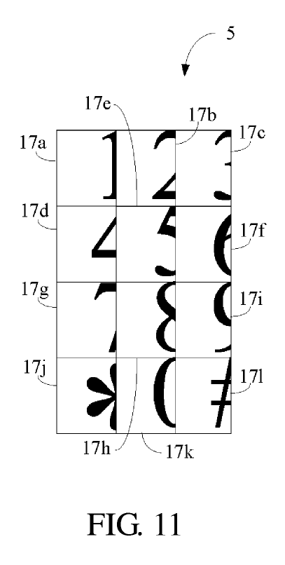

FIG. 11 depicts the fifth embodiment of this invention, which is an input device 5. In this embodiment, the input device 5 is a touch panel of a handheld electronic apparatus, e.g., a mobile phone. In other embodiments, however, the input device may also be a physical keyboard. Furthermore, the input device 5 may also be used in other handheld electronic apparatuses, a keyboard, a phone, a notebook computer or other electronic products provided with keys. The input device 5 of this embodiment comprises a plurality of keys 17a˜17l. The input device 5 of this embodiment has substantially the same circuit connections as the first embodiment, and thus, this will not be further described herein.

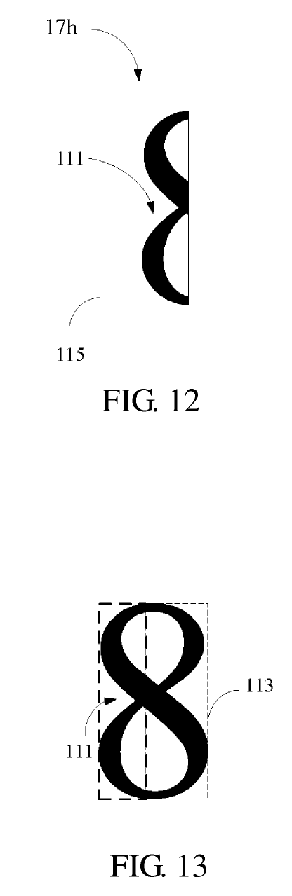

In reference to FIGS. 12 and 13, this embodiment differs from the first embodiment in that the pattern 111 is a left portion of the first complete character 113, which occupies 45% in area of the first complete character 113. In other words, the pattern 111 occupies 45% of the first complete character 113, i.e., the left portion presented with the pattern 111 is a left area captured from the first complete character 113 that occupies 45% of the first complete character 113. The 45% adopted herein is adapted to allow the left portions of the numerals on all keys 17a˜17l to represent character features of the corresponding numerals. The so-called character features in turn allow the user to recognize the individual numerals. However, it should be noted that the percentage of the left portion which occupies the first complete character 113, is not merely limited to 45%, and may range from 45% to 100% in other embodiments. In practice, a user may readily recognize the numerals represented by the individual keys with the character features presented on the keys, and then press one of the keys 17a˜17l as needed. Each of the keys is adapted to generate a corresponding key-pressing signal, which is routed through a circuit board and transmitted to the control circuit. Upon receiving the corresponding key-pressing signal, the control circuit proceeds to process the signal so that the input device 5 can give a corresponding visual display or take other actions.

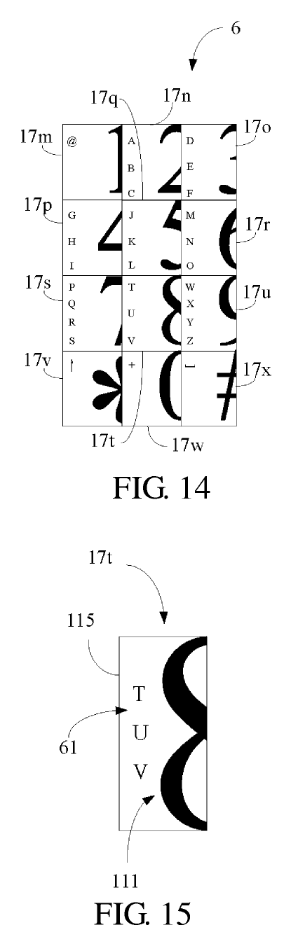

FIG. 14 depicts the sixth embodiment of this invention, which is an input device 6. The input device 6 comprises a plurality of keys 17m˜17x. The input device 6 of the sixth embodiment has substantially the same circuit connections as the input device 5 of the fifth embodiment. The captured portion is also a left area that occupies 45% of the first complete character and will not be further described herein. The input device 6 of this embodiment is used in a physical keyboard or a virtual key of a handheld electronic apparatus. Typically, in a physical keyboard or virtual keys of a mobile phone, each key is able to input different characters by switching the input methods. Accordingly, as depicted in FIG. 15, this embodiment differs from the fifth embodiment in that each of the keys in the input device 6 further comprises a plurality of second complete characters 61 to meet the need for different characters in different input methods. The second complete characters 61 includes A˜Z, ↑, +, [symbol] , which are dispersedly arranged on individual keys respectively with each key having a particular number of such characters thereon. The contents A˜Z, ↑, +, [symbol] of the second complete characters 61 set forth herein are only for purpose of illustration, and may also be a phonetic notation, a punctuation mark, a character or an icon in other embodiments. As depicted in FIG. 15, the second complete characters 61 of this embodiment are arranged to the left of the pattern 111. In other embodiments, however, the second complete characters 61 are not just limited to such a location, but may also be formed at any locations on the key body 115. Furthermore, the electronic apparatus that adopts the input device 6 are not merely limited to what is described above as well as the amount and the arrangement of the second complete characters 61.

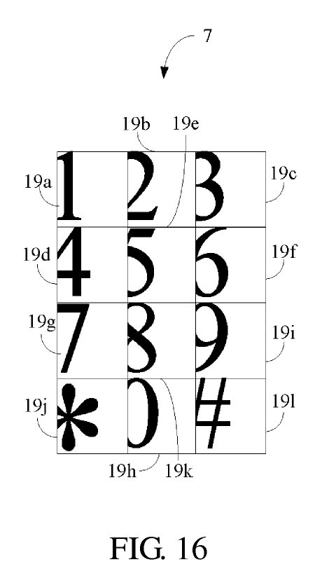

FIG. 16 depicts the seventh embodiment of this invention, which is an input device 7. In this embodiment, the input device 7 is a touch panel of a handheld electronic apparatus, e.g., a mobile phone. In other embodiments, however, the input device may also be a physical keyboard. Furthermore, the input device 7 may also be used in other handheld electronic apparatuses, a keyboard, a phone, a notebook computer or other electronic products provided with keys. The input device 7 of this embodiment comprises a plurality of keys 19a˜19l. The input device 7 of this embodiment has substantially the same circuit connections as the first embodiment, and thus, this will not be further described herein.

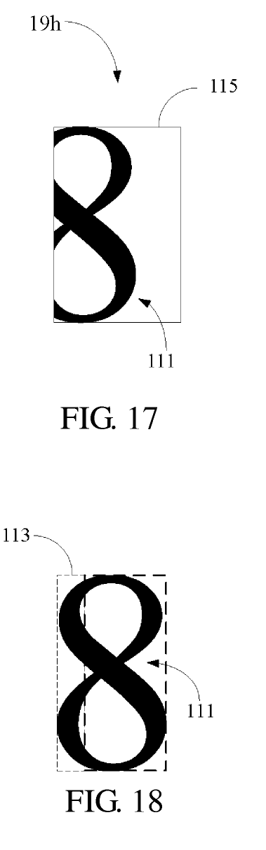

In reference to FIGS. 17 and 18, this embodiment differs from the first embodiment in that the pattern 111 is a right portion of the first complete character 113, which occupies 70% in area of the first complete character 113. In other words, the pattern 111 occupies 70% in area of the first complete character 113, i.e., the right portion presented with the pattern 111 is a right area captured from the first complete character 113 that occupies 70% of the first complete character 113. The 70% adopted herein is adapted to allow the right portions of numerals on all keys 19a˜19l to represent character features of the corresponding numerals, and the so-called character features in turn allow the user to recognize the individual numerals. However, it should be noted that the percentage of the right portion which occupies the first complete character 113, is not merely limited to 70%, and may range from 70% to 100% in other embodiments. In practice, a user may readily recognize the numerals represented by the individual keys with the character features presented on the keys, and then press one of the keys 19a˜19l as needed. Each of the keys is adapted to generate a corresponding key-pressing signal, which is routed through a circuit board and transmitted to the control circuit. Upon receiving the corresponding key-pressing signal, the control circuit processes the signal so that the input device 7 can give a corresponding visual display or take other actions.

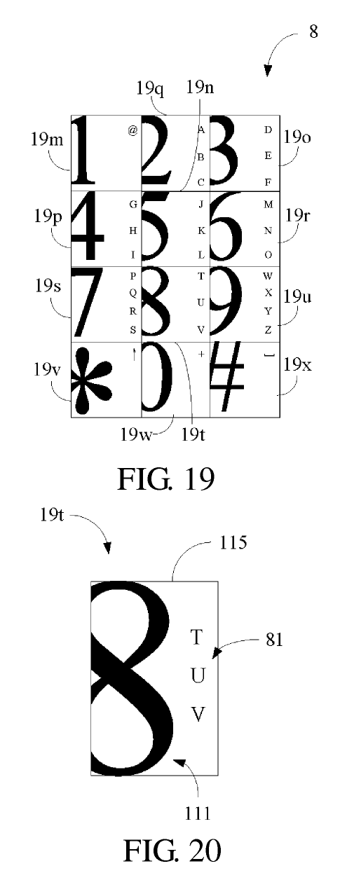

FIG. 19 depicts the eighth embodiment of this invention, which is an input device 8. The input device 8 comprises a plurality of keys 19m˜19x. The input device 8 of the eighth embodiment has substantially the same circuit connections as the input device 7 of the seventh embodiment, and the captured portion is also a right area that occupies 70% of the first complete character. Thus, these will not be further described herein. The input device 8 of this embodiment is used in a physical keyboard or a virtual key of a handheld electronic apparatus. Typically, in a physical keyboard or virtual keys of a mobile phone, each key is able to input different characters by switching the input methods. Accordingly, as depicted in FIG. 20, this embodiment differs from the seventh embodiment in that each of the keys in the input device 8 further comprises a plurality of second complete characters 81 to meet the need for different characters in different input methods. The second complete characters 81 includes A˜Z, ↑, +, [symbol] , which are dispersedly arranged on individual keys respectively with each key having a particular number of such characters thereon. The contents A˜Z, ↑, +, [symbol] of the second complete characters 81 set forth herein are only for purpose of illustration, and may also be a phonetic notation, a punctuation mark, a character or an icon in other embodiments. Each of the second complete characters 81 are arranged to the right of the pattern 111. In other embodiments, however, the second complete characters 81 are not just limited to such a location, but may also be formed at any locations on the key body 115. Furthermore, the electronic apparatus that adopts the input device 8 are not merely limited to what is described above as well as the amount and the arrangement order of the second complete characters 81.

It shall be further noted that other aspects of this invention will readily occur to those skilled in the art on basis of the features of this invention. Therefore, the fonts, sizes, and colors of the characters, the locations, amount, and shapes of the blocks captured from the character features, the spatial ratio of individual keys or the whole keyboard, the arrangement, position and spacing of the keys in the keyboard, as well as the associated design of the individual keys are all not limited to what is described in the above embodiments. In other words, this invention provides a brand new concept that is quite different from the design customs of conventional and typical keys. Apart from maintaining the original size of the pattern on a reduced key area, this invention may also present a pattern with an appropriately scaled-up size on the original key area. In the latter case, the character presented by the pattern on the key may be incomplete because the key size is unchanged. However, these characters can still be recognized by users for dialing numbers or making an input. This is because the incomplete pattern is still an effective and recognizable symbol, which can prevent input errors due to recognition.

It follows from the above description that in the input device of this invention, patterns with character features are designed according to the unique character features of the individual characters. The characters on the keyboard can still be recognized even when the input device is shrunk, thus allowing the user to recognize the needed characters. In this way, the limit to which input devices of prior art can be shrunk in size is definitely improved.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A key of an input device, comprising:
a pattern, which is a portion of a first complete character, and comprises a character feature which is adapted to have a user to recognize the first complete character.

2. The key as claimed in claim 1, wherein the pattern is an upper portion of the first complete character.

3. The key as claimed in claim 2, wherein the upper portion occupies at least 55% of the first complete character.

4. The key as claimed in claim 1, wherein the pattern is a lower portion of the first complete character.

5. The key as claimed in claim 4, wherein the lower portion occupies at least 60% of the first complete character.

6. The key as claimed in claim 1, wherein the pattern is a left portion of the first complete character.

7. The key as claimed in claim 6, wherein the left portion occupies at least 45% of the first complete character.

8. The key as claimed in claim 1, wherein the pattern is a right portion of the first complete character.

9. The key as claimed in claim 8, wherein the right portion occupies at least 70% of the first complete character.

10. The key as claimed in claim 1, wherein the first complete character is one of a numeral, a letter, a phonetic notation, a punctuation mark, a character and an icon.

11. The key as claimed in claim 1, further comprising at least a second complete character, wherein the at least the second complete character is one of a numeral, a letter, a phonetic notation, a punctuation mark, a character and an icon.

12. The key as claimed in claim 1, wherein the key is one of a physical key and a virtual key.

13. An input device, comprising:
a plurality of keys as claimed in claim 1.

14. The input device as claimed in claim 13, wherein the pattern is an upper portion of the first complete character.

15. The input device as claimed in claim 14, wherein the upper portion occupies at least 55% of the first complete character.

16. The input device as claimed in claim 13, wherein the pattern is a lower portion of the first complete character.

17. The input device as claimed in claim 16, wherein the lower portion occupies at least 60% of the first complete character.

18. The input device as claimed in claim 13, wherein the pattern is a left portion of the first complete character.

19. The input device as claimed in claim 18, wherein the left portion occupies at least 45% of the first complete character.

20. The input device as claimed in claim 13, wherein the pattern is a right portion of the first complete character.

21. The input device as claimed in claim 20, wherein the right portion occupies at least 70% of the first complete character.

22. The input device as claimed in claim 13, wherein the first complete character is one of a numeral, a letter, a phonetic notation, a punctuation mark, a character and an icon.

23. The input device as claimed in claim 13, further comprising at least a second complete character, wherein the at least the second complete character is one of a numeral, a letter, a phonetic notation, a punctuation mark, a character and an icon.

24. The input device as claimed in claim 13, wherein the input device is one of a physical keyboard and a virtual keyboard.

25. The input device as claimed in claim 13, being adapted for one of an electronic handheld device, a keyboard, a phone and a notebook.
